(19) United States
(12) Patent Application Publication
(10) Pub. No.: US 2002/0182860 A1
(43) Pub. Date: Dec. 5, 2002

(54) Method of forming self-aligned silicide layers on semiconductor devices

(76) Inventors: Cheng-Kuo Yuan, Hsinchu (TW); Chi-Wei Chou, Hsinchu (TW); Jerry Lin, Hsinchu (TW)

Correspondence Address: BIRCH STEWART KOLASCH & BIRCH, PO BOX 747, FALLS CHURCH, VA, 22040-0747, US

(21) Appl. No.: 09/865,516

(22) Filed: May 29, 2001

(51) Int. Cl. H01L 21/44

(52) U.S. Cl. 438/655

(57) ABSTRACT

A method of forming self-aligned silicide layers on semiconductor devices. The method includes a metal sputtering step which sputters a metal material onto a semiconductor device in an environment with a temperature of at least 400° C., an etching step which selectively removes unreacted metal and reacted metal remainder, and a high temperature annealing step which forms a self-aligned silicide layer by rapidly raising the temperature and annealing. Using this method, an inter-mediate can be formed during the metal sputtering process. Therefore, the invention takes out one rapid thermal annealing process in the self-aligned silicide process, reducing the cycle time and cost, and increasing the yield.

### BACKGROUND OF THE INVENTION

1. Field of Invention

The invention relates to a method of forming a self-aligned silicide layer on a semiconductor device. More particularly, the method uses high temperature metal sputtering to form a self-aligned metal silicide layer on the semiconductor device.

2. Related Art

In semiconductor device manufacturing processes, to reduce the resistance of a conduction layer, a metal silicide, or silicide for short, layer is usually formed on polysilicon. As the integrity of semiconductor devices increases, to reduce the sheet resistance of the drain and source and to ensure a perfect shallow junction between metal and semiconductor devices (e.g. MOS), a method called the self-aligned silicide manufacturing process is gradually applied in VLSI productions. This procedure is also called the salicide process.

As described before, the conventional self-aligned silicide process contains a metal sputtering step, a first rapid thermal annealing step, a selective etching step, and a second rapid thermal annealing step. Taking Co (cobalt) sputtering as an example, the temperature in the first rapid thermal annealing step is maintained at about 500° C. for 30 seconds, forming an inter-mediate such as CoSi or Co₂Si. Afterwards, a self-aligned silicide is formed after the selective etching step and the second rapid thermal annealing step.

The above method contains two rapid thermal annealing processes. As is well known, however, rapid thermal annealing to form silicide at high temperatures is not easy to be controlled. It often lowers the yield and increases the cost. Therefore, how to decrease the number of times of rapid thermal annealing is an important issue. Decreasing the number of times of rapid thermal annealing does not only reduce the cycle time, but also avoids the defect of difficult control in forming silicide at high temperatures. Thus, the invention can effectively reduce the cost.

### SUMMARY OF THE INVENTION

In view of the foregoing, an object of the invention is to provide a method of forming self-aligned silicide layers on semiconductor devices with reduced number of times of rapid thermal annealing in order to reduce the cycle time, to increase the yield, and to lower the cost.

The invention is featured in that an in-situ inter-mediate is formed in the metal sputtering process by increasing the reaction temperature in metal sputtering, thus getting rid of one time of rapid thermal annealing.

To achieve the above object, the invention provides a method of forming self-aligned silicide layers on semiconductor devices. The method includes a metal sputtering step for sputtering a metal material on a semiconductor device, an etching step for selectively etching and removing unreacted metal and reacted metal remainder, and a high temperature annealing step for forming a self-aligned silicide layer by rapid thermal annealing.

Using the disclosed method, an in-situ inter-mediate can be formed in the metal sputtering process in the metal sputtering step. The invention can thus take out the first rapid thermal annealing needed in the conventional self-aligned silicide manufacturing process.

### BRIEF DESCRIPTION OF THE DRAWINGS

The present invention will become more fully understood from the detailed description given hereinbelow illustration only, and thus are not limitative of the present invention, wherein:

FIG. 1 is a schematic side cross-sectional view of a MOS device with a cobalt silicide formed thereon, illustrating the disclosed method of forming a self-aligned silicide layer on a semiconductor device; and

FIG. 2 is another schematic side cross-sectional view of the MOS device in FIG. 1 after the etching step and the high temperature annealing step according to the invention.

### DETAILED DESCRIPTION OF THE INVENTION

Before detailed description of the invention, it should be mentioned that a MOS semiconductor device is used herein as an example for explaining a preferred embodiment.

The method of forming a self-aligned silicide layer on a semiconductor device consists of a metal sputtering step, an etching step, and a high temperature annealing step.

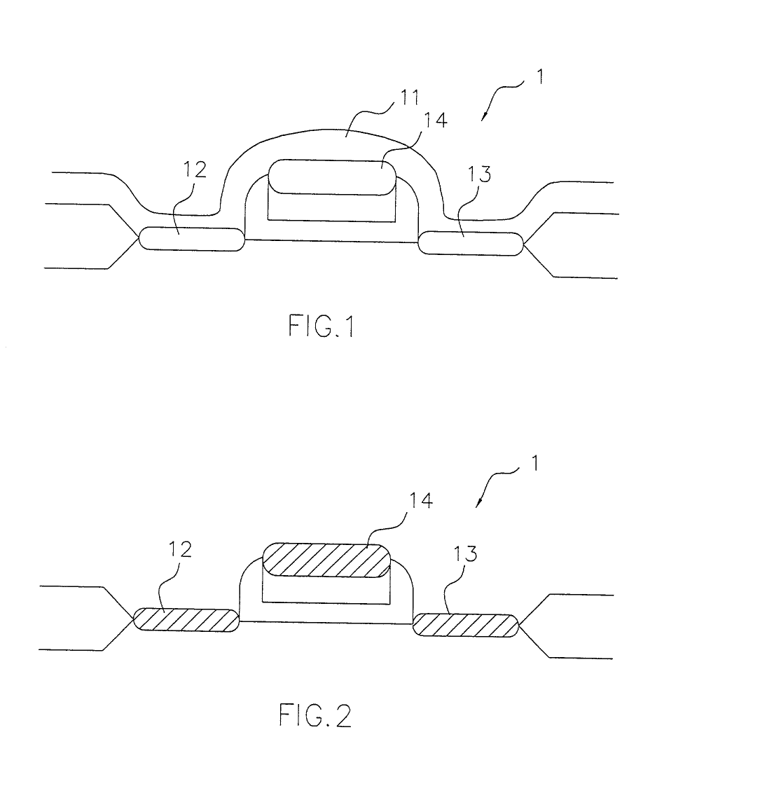

In the metal sputtering step, a metal material is sputtered on a semiconductor device with the temperature being kept at no lower than 400° C. In the current embodiment, as shown in FIG. 1, the temperature is kept between 400° C. and 450° C. Cobalt as the metal material is sputtered onto a MOS device 1 so as to form cobalt silicide layer 11 which has a cobalt inter-mediate (CoSi or Co₂Si) on the forming areas of the drain 12, source 13, and gate 14 of the MOS device 1.

In the etching step, referring to FIG. 2, unreacted cobalt and reacted cobalt remainder, not necessarily left as pure cobalt, are removed by selective etching. In the current embodiment, ammonia and hydrogen peroxide are used for etching.

In the high temperature annealing step, a self-aligned silicide layer is formed by rapid thermal annealing. More explicitly, the temperature is rapidly raised to about 800° C. and kept at the temperature for 30 seconds, turning the inter-mediate into CoSi₂.

Using the disclosed method of forming self-aligned silicide layers on semiconductor devices can form in-situ inter-mediate during the high temperature metal sputtering process. Consequently, one less rapid thermal annealing process is needed in the self-aligned silicide process, greatly shortening the manufacturing time. Since the disclosed method eliminates one rapid thermal annealing process, it can avoid the difficulty in controlling the rapid temperature increase. Thus, the yield can be increased.

In conclusion, the method of forming self-aligned silicide layers on semiconductor devices disclosed herein can shorten the cycle time while increasing the yield and lowering the cost.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method of forming a self-aligned silicide layer on a semiconductor device, which comprises:
a metal sputtering step, which sputters a metal material onto the semiconductor device at a temperature of at least 400° C.;
an etching step, which removes unreacted and reacted metal remainder by selective etching; and
a high temperature annealing step, which forms a self-aligned silicide layer by rapid thermal annealing.

2. The method of claim 1, wherein the metal material is cobalt.

3. The method of claim 1, wherein the temperature in the metal sputtering step is controlled between 400° C. and 450° C.

4. The method of claim 1, wherein the temperature in the high temperature annealing step is rapidly raised to about 800° C. and maintained for 30 seconds.

5. The method of claim 2, wherein the self-aligned silicide layer is CoSi₂.
